(19) United States
(12) Patent Application Publication
(10) Pub. No.: US 2010/0065959 A1
(43) Pub. Date: Mar. 18, 2010

(54) SEMICONDUCTOR PACKAGE AND METHOD OF MANUFACTURING THE SAME, AND SEMICONDUCTOR DEVICE

(75) Inventors: Akio Horiuchi, Nagano (JP); Hiroshi Yokota, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/542,987

(22) Filed: Aug. 18, 2009

(30) Foreign Application Priority Data
Sep. 18, 2008 (JP) 2008-238798

(51) Int. Cl. H01L 23/488; H01L 23/48; H01L 21/60; H01L 21/58

(52) U.S. Cl. 257/692; 438/121; 257/773; 438/125; 257/E23.023; 257/E23.01; 257/E21.509; 257/E21.505; 438/118

(57) ABSTRACT

A semiconductor package includes a wiring substrate having a connection pad on both surface sides respectively, and a supporting plate provided on one surface side of the wiring substrate and formed of an insulator in which an opening portion is provided in a portion corresponding to the connection pad. The external connection terminals (the lead pins, or the like) are provided on the connection pads on the surface of the wiring substrate on which the supporting plate is provided, and the semiconductor chip is mounted on the connection pads on the opposite surface.

### CROSS-REFERENCE TO RELATED APPLICATIONS

This application is based on and claims priority of Japanese Patent Application No. 2008-238798 filed on Sep. 18, 2008, the entire contents of which are incorporated herein by reference.

### BACKGROUND OF THE INVENTION

1. Field of the Invention

The present invention relates to a semiconductor package on which a semiconductor chip is mounted and a method of manufacturing the same and a semiconductor device.

2. Description of the Related Art

In the prior art, there is the semiconductor package for constructing the semiconductor device by mounting the semiconductor chip. In such semiconductor chip, the semiconductor chip is mounted on one surface of the wiring substrate, and the external connection terminals are provided on the other surface.

In Patent Literature 1 (Patent Application Publication (KOKAI) 2000-323613), such a technology is disclosed that, in the multilayer wiring substrate for the semiconductor device, the semiconductor element mounting layer is formed as a flat surface as possible by stacking sequentially the wiring layers and the connection layers from the semiconductor element mounting layer side to the direction of the external connection terminal fitting layer. Also, it is set forth that the frame body made of metal is provided on the peripheral portion of the substrate to reinforce.

Also, in Patent Literature 2 (Patent Application Publication (KOKAI) 2003-142617), it is set forth that, in the package for the semiconductor device, the insulating metal plate in which through holes corresponding to the external connection terminal pads are provided and the insulating process is applied to the whole surface is adhered onto the external connection terminal fitting layer and then the frame body made of metal is joined to the semiconductor element mounting layer, whereby the occurrence of a warp is prevented and also the handling in transportation, or the like is facilitated.

In recent years, with the higher performance of the semiconductor element, in the semiconductor package, higher density and thinner type of the wiring substrate are required. When the wiring substrate of the semiconductor package is made thin (e.g., a thickness is about 0.4 mm or less), a mechanical strength of the semiconductor package becomes considerably small. Therefore, various problems become obvious.

In particular, when the lead pins are used as the external connection terminals, the wiring substrate is readily bent and deformed in fitting the lead pins. Therefore, it becomes difficult to provide the lead pins with good reliability. This problem will be explained in more detail in the column of the related art described later.

### SUMMARY OF THE INVENTION

It is an object of the present invention to provide a semiconductor package capable of obtaining a satisfactory mechanical strength even when the wiring substrate made thin is employed and a method of manufacturing the same and a semiconductor device.

The present invention is concerned with a semiconductor package, which includes a wiring substrate having a connection pad on both surface sides respectively; and a supporting plate provided on one surface side of the wiring substrate and formed of an insulator in which an opening portion is provided in a portion corresponding to the connection pad.

In the present invention, the supporting plate (the resin layer containing fiber reinforcing material, or the like) made of an insulator having the opening portions in the portions corresponding to the connection pads is formed on one surface of the wiring substrate. Therefore, even when the wiring substrate is made thin with the high-density mounting, the wiring substrate is reinforced and a sufficient rigidity can be obtained.

Also, in a situation that the wiring substrate is made thin more and more, the wiring substrate is bent and deformed when the lead pins are fitted to the wiring substrate. Therefore, according to the equipment and the jig in the prior art, it is difficult to fit the lead pins with good reliability.

In the present invention, the wiring substrate is reinforced by the supporting plate. Therefore, even when the wiring substrate is made thin, the lead pins can be fitted with good reliability by the equipment and the jig in the prior art, and a development cost can be suppressed. Also, a tensile strength of the lead pins can be measured precisely.

Also, the present invention is concerned with a method of manufacturing a semiconductor package, which includes the steps of preparing a wiring layer that is equipped with a connection pad on both surface sides respectively; and forming a supporting plate that is provided on one surface side of the wiring substrate and formed of an insulator in which an opening portion is provided in a portion corresponding to the connection pad.

In one preferred embodiment of the present invention, the supporting plate is formed of a sheet-like resin layer. Then, the resin layer is adhered onto the wiring substrate by the adhesive layer, and then the opening portions are formed by processing the resin layer and the adhesive layer.

Alternatively, the sheet-like resin layer or the ceramic plate, in which the opening portions corresponding to the connection pads are provided, and the adhesive layer, in which the opening portions are provided, may be prepared. Then, the resin layer or the ceramic plate may be adhered to the wiring substrate by the adhesive layer.

As explained above, in the present invention, even when the wiring substrate made thin is employed, a satisfactory mechanical strength can be obtained.

### BRIEF DESCRIPTION OF THE DRAWINGS

FIGS. 1A and 1B are sectional views (#1) illustrating a problem caused in fitting lead pins on a wiring substrate, in a semiconductor package in the related art;

FIGS. 2A and 2B are sectional views (#2) illustrating the problem caused in fitting the lead pins on the wiring substrate, in the semiconductor package in the related art;

FIGS. 3A and 3B are a sectional view and a plan view (#1) showing a method of manufacturing a semiconductor package according to a first embodiment of the present invention respectively;

FIGS. 4A and 4B are sectional views (#2) showing the method of manufacturing the semiconductor package according to the first embodiment of the present invention;

FIG. 5 is a sectional view (#3) showing the method of manufacturing the semiconductor package according to the first embodiment of the present invention;

FIGS. 6A and 6B are sectional views showing a second forming method of a supporting plate, in the method of manufacturing the semiconductor package according to the first embodiment of the present invention;

FIGS. 7A and 7B are sectional views (#1) showing a third forming method of a supporting plate, in the method of manufacturing the semiconductor package according to the first embodiment of the present invention;

FIGS. 8A and 8B sectional views (#2) showing the third forming method of a supporting plate, in the method of manufacturing the semiconductor package according to the first embodiment of the present invention;

FIGS. 9A and 9B are sectional views showing a fourth forming method of a supporting plate, in the method of manufacturing the semiconductor package according to the first embodiment of the present invention;

FIGS. 10A and 10B are sectional views (#4) showing the method of manufacturing the semiconductor package according to the first embodiment of the present invention;

FIGS. 11A and 11B are sectional views (#5) showing the method of manufacturing the semiconductor package according to the first embodiment of the present invention;

FIG. 12 is a sectional view showing a semiconductor package according to the first embodiment of the present invention;

FIG. 13 is a sectional view showing another semiconductor package according to the first embodiment of the present invention;

FIG. 14 is a sectional view showing further another semiconductor package according to the first embodiment of the present invention;

FIG. 15 is a sectional view showing a semiconductor device according to the first embodiment of the present invention;

FIG. 16 is a sectional view showing another semiconductor device according to the first embodiment of the present invention;

FIGS. 17A and 17B are sectional views (#1) showing a method of manufacturing a semiconductor package according to a second embodiment of the present invention; and

FIG. 18 is a sectional view (#2) showing the method of manufacturing the semiconductor package according to the second embodiment of the present invention.

### DETAILED DESCRIPTION OF THE PREFERRED EMBODIMENTS

Embodiments of the present invention will be explained with reference to the accompanying drawings hereinafter.

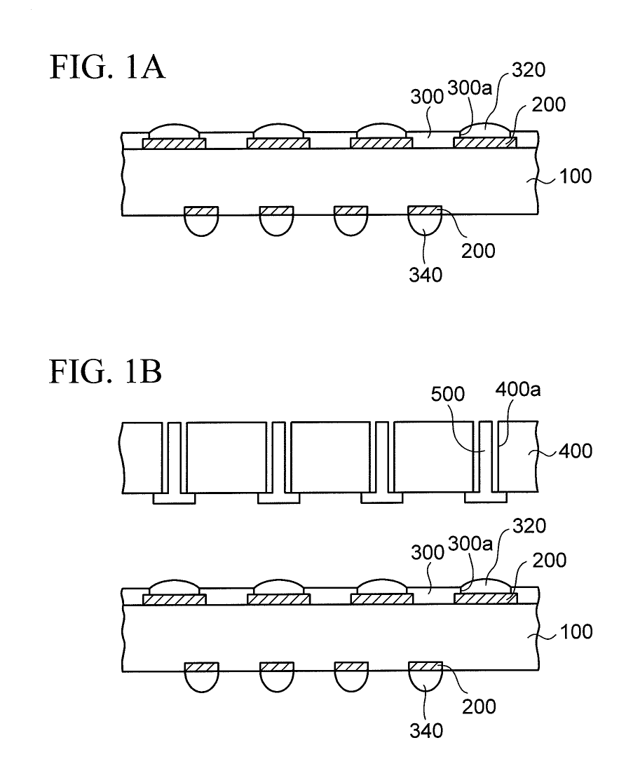

Prior to the explanation of embodiments of the present invention, the problem of the semiconductor package in the related art will be explained hereunder. In the semiconductor package in the related art, a wiring substrate 100 as shown in FIG. 1A is employed. The wiring substrate 100 is a coreless wiring substrate, and is made thin to about 0.4 mm. A predetermined build-up wiring layer (not shown) is formed in the wiring substrate 100, and connection pads 200 connected to the build-up wiring layer are provided on both surface side of the wiring substrate 100 respectively.

A solder resist 300 in which opening portions 300a are provided on the connection pads 200 is formed on the upper surface side of the wiring substrate 100. A solder layer 320 used to fix the lead pin is formed on the connection pads 200 on the upper surface side of the wiring substrate 100 respectively. A solder bump 340 for mounting the semiconductor chip is formed on the connection pads 200 on the lower surface side of the wiring substrate 100 respectively.

Then, as shown in FIG. 1B, a pin mounting jig 400 in which a plurality of insertion holes 400a corresponding to the connection pads 200 on the upper surface side of the wiring substrate 100 are provided is prepared. Also, a lead pin 500 is inserted into the insertion holes 400a in the pin mounting jig 400 respectively.

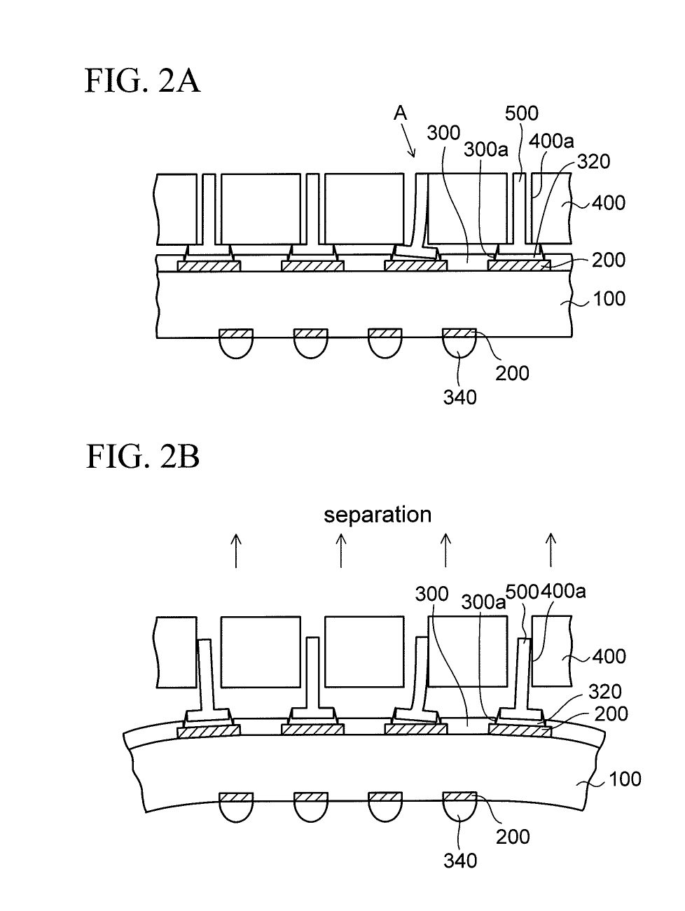

Then, as shown in FIG. 2A, while opposing the pin mounting jig 400, in which a plurality of lead pins 500 are aligned, to the upper surface side of the wiring substrate 100, the head portions of the lead pins 500 are pushed onto the solder layers 320 provided on the connection pads 200 of the wiring substrate 100. Then, the solder layers 320 are reflow-heated. Accordingly, the lead pins 500 are fixed to the connection pads 200 of the wiring substrate 100 by the solder layer 320 respectively.

Then, as shown in FIG. 2B, the pin mounting jig 400 is separated from the wiring substrate 100. At this time, the lead pins 500 which are fitted to the wiring substrate 100 in a state to incline often exist among a large number of lead pins 500 in no small way (A portion in FIG. 2A). Therefore, upon separating the pin mounting jig 400 from the wiring substrate 100, the inclined lead pins 500 contact the insertion holes 400a of the pin mounting jig 400 and act as a resistance during the separation.

At this time, the wiring substrate 100 is made thin and its rigidity is low. Therefore, the wiring substrate 100 is bent and deformed in separating the pin mounting jig 400. As a result, it becomes difficult to separate the pin mounting jig 400.

In this manner, when the lead pins 500 are fitted to the wiring substrate 100 made thin, in the method of employing the conventional equipment and jig, handling becomes difficult. The pin mounting jig 400 is cited as an example. In this case, in various equipments that handle the wiring substrate 100, the wiring substrate 100 is ready to deform due to an external stress caused in picking up the wiring substrate 100 or sucking the wiring substrate 100.

Also, at the time of measuring a tensile strength of the lead pin 500, the wiring substrate 100 is bent and deformed by pulling the lead pin 500 because a rigidity of the wiring substrate 100 is low. When the lead pins 500 are pulled forcibly in a state that the wiring substrate 100 is bent, there is such a tendency that the lead pins 500 are separated together with the connection pads of the wiring substrate 100. Thus, it is difficult to measure a precise tensile strength of the lead pin 500 itself.

According to embodiments of the present invention illustrated hereinafter, the above-mentioned failure can be solved.

### First Embodiment

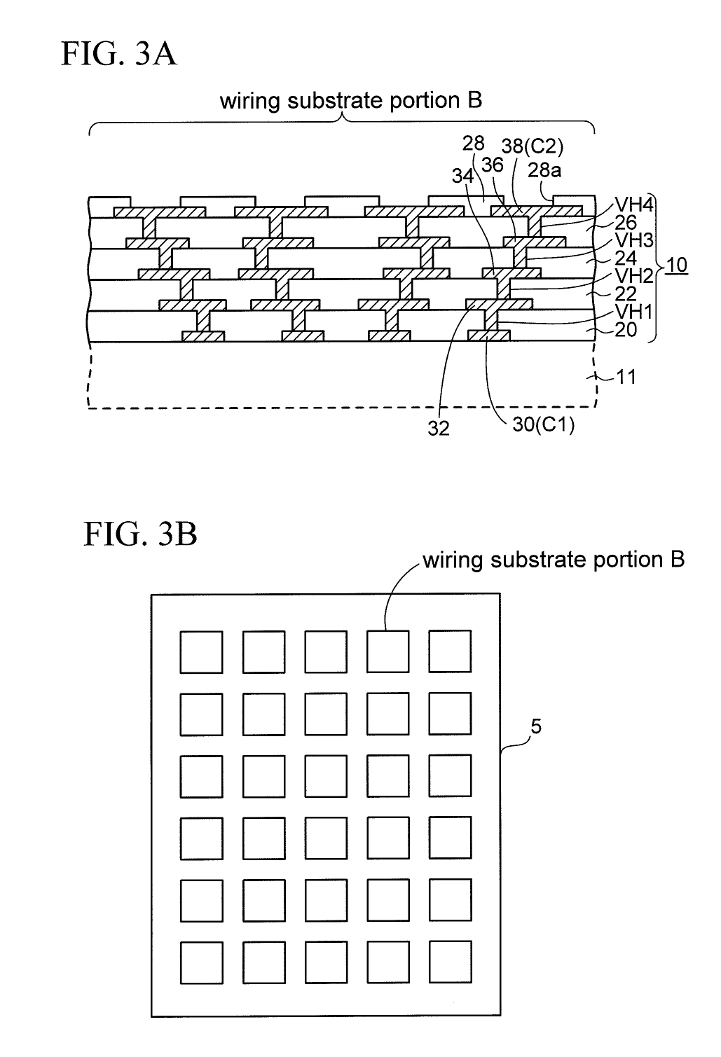

FIG. 3 to FIG. 10 are sectional views showing a method of manufacturing a semiconductor package according to a first embodiment of the present invention.

In the method of manufacturing the semiconductor package according to the first embodiment of the present invention, first, a wiring substrate 10 shown in FIG. 3A is prepared. The wiring substrate 10 shown in FIG. 3A corresponds to one wiring substrate portion B of a large-size substrate 5 for multi production shown in FIG. 3B. In an example of FIG. 3B, five wiring substrate portions and six wiring substrate portions are defined in the lateral direction and the longitudinal direction in the large-size substrate 5 respectively, and individual wiring substrate portions B are obtained by cutting off the large-size substrate in the later step.

In the wiring substrate 10 in FIG. 3A, first wiring layers 30 are embedded on the lower portion of a first interlayer insulating layer 20 to expose their lower surfaces thereof, and the first wiring layers 30 constitute chip connection pads C1 for mounting the semiconductor chip. The first wiring layer 30 may be formed of the chip connection pad C1 only or the chip connection pad C1 may be connected to the wiring layer.

Also, first via holes VH1 reaching the first wiring layer 30 respectively are formed in the first interlayer insulating layer 20. Also, second wiring layers 32 each connected to the first wiring layer 30 via the first via hole VH1 (via conductor) are formed on the first interlayer insulating layer 20.

Also, a second interlayer insulating layer 22 is formed on the second wiring layers 32, and second via holes VH2 reaching the second wiring layer 32 respectively are formed in the second interlayer insulating layer 22. Also, third wiring layers 34 each connected to the second wiring layer 32 via the second via hole VH2 (via conductor) are formed on the second interlayer insulating layer 22.

Also, similarly a third interlayer insulating layer 24 is formed on the third wiring layers 34, and third via holes VH3 reaching the third wiring layer 34 respectively are formed in the third interlayer insulating layer 24. Also, fourth wiring layers 36 each connected to the third wiring layer 34 via the third via hole VH3 (via conductor) are formed on the third interlayer insulating layer 24.

Also, similarly a fourth interlayer insulating layer 26 is formed on the fourth wiring layers 36, and fourth via holes VH4 reaching the fourth wiring layer 36 respectively are formed in the fourth interlayer insulating layer 26. Also, fifth wiring layers 38 each connected to the fourth wiring layer 36 via the fourth via hole VH4 (via conductor) are formed on the fourth interlayer insulating layer 26.

In FIG. 3A, pad portions of the fifth wiring layers 38 are shown, and the fifth wiring layers 38 constitute connection terminal pads C2 for connecting the external connection terminals (lead pins, or the like). The fifth wiring layer 38 may be formed of the connection terminal pad C2 only, or the connection terminal pad C2 may be connected to the wiring layer.

A solder resist 28 in which opening portions 28a are provided on the connection terminal pads C2 is formed on the fourth interlayer insulating layer 26. A contact layer (not shown) formed by stacking nickel/gold plating layers sequentially from the bottom is provided on respective surfaces of the chip connection pads C1 and the connection terminal pads C2. Alternatively, the contact layer may be formed by stacking nickel/palladium/gold plating layers sequentially from the bottom.

The first to fifth wiring layers 30, 32, 34, 36, 38 are formed of copper, or the like, and the first to fourth interlayer insulating layers 20, 22, 24, 26 are formed of an epoxy resin, a polyimide resin, or the like.

The wiring substrate 10 used in the first embodiment is a coreless wiring substrate which is made thin and does not have a core substrate, and its total thickness is set to 0.2 mm to 0.4 mm. Such wiring substrate 10 made thin is manufactured by forming a predetermined build-up wiring layer on a temporary substrate 11 (shown by a broken line in FIG. 3A) in a peelable state, and then removing the temporary substrate 11 from the build-up wiring layer.

In an example in FIG. 3A, the five-layered build-up wiring layer is illustrated. But the number of stacked wiring layers can be set arbitrarily.

In the first embodiment, the coreless wiring substrate is illustrated as the wiring substrate 10 of thin type. But the wiring substrate with core having a core substrate of thin type in a center portion in the thickness direction may be employed. Although not particularly shown, the wiring substrate with core is constructed by forming the build-up wiring layer, which is connected mutually via through electrodes provided in the core substrate, on both surface sides of the core substrate. Also in the case of the wiring substrate with core, a total thickness is set to 0.2 mm to 0.4 mm.

The wiring substrate 10 of the first embodiment may have the connection pads on both surface sides, and various wiring substrates can be employed.

Such wiring substrate 10 made thin is equipped with the high density wirings for mounting the high-performance semiconductor chip, and can respond to size reduction/thin type/higher density of the electronic equipment. In contrast, the wiring substrate 10 made thin has a small mechanical strength as the substrate itself and has such a demerit that, when the external stress is applied, this substrate is readily bent and deformed.

For this reason, in the first embodiment, as explained subsequently, a mechanical strength of the wiring substrate 10 should be reinforced by providing a reinforcing plate to the surface of the wiring substrate 10 onto which the external connection terminals are provided (surface on the connection terminal pad C2 side).

(First forming method of supporting plate)

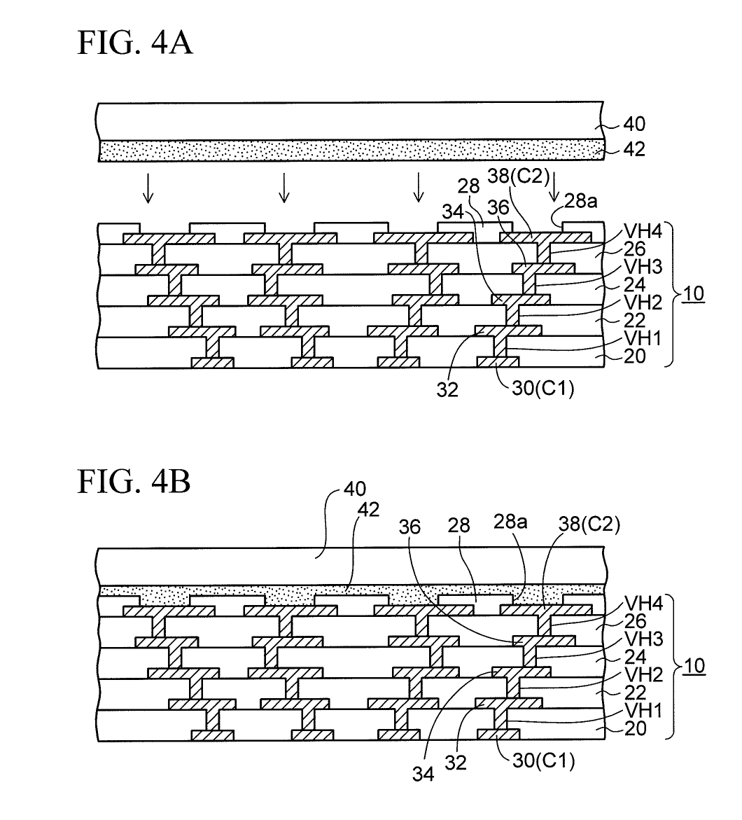

As shown in FIG. 4A, a sheet-like glass epoxy resin layer 40 whose thickness is 0.1 mm to 0.2 mm is prepared as a supporting plate. A sheet-like adhesive layer 42 used to adhere is provided under the glass epoxy resin layer 40. The glass epoxy resin layer 40 is an example of the resin layer containing fiber reinforcing material, and is obtained by impregnating a glass fiber with an epoxy resin and curing the resin. The resin layer containing fiber reinforcing material such as the glass epoxy resin layer 40, or the like has a strong rigidity, and is served preferably as the supporting plate.

Also, as the resin layer containing fiber reinforcing material, an aramid-epoxy resin layer formed by impregnating aramid fibers with an epoxy resin, a carbon-epoxy resin layer formed by impregnating carbon fibers with an epoxy resin, or the like may be employed, in addition to the glass epoxy resin layer 40. Respective fibers of the resin layer containing fiber reinforcing material may be formed of a woven fabric or a nonwoven fabric.

Alternatively, an epoxy resin layer in which fillers such as silica, and the like are contained (filler containing resin layer) may be employed.

As the adhesive layer 42, a thermosetting resin such as prepreg, epoxy resin, or the like is employed. The prepreg is the intermediate material in which the fibers such as glass, or the like are impregnated previously with a resin such as an epoxy resin, or the like corresponding to the adhesive. Those thermosetting resin is a resin in the B stage (semi-cured state), and functions as the adhesive when cured by the heat treatment.

As shown in FIG. 4B, the glass epoxy resin layer 40 on the lower surface side of which the adhesive layer 42 is provided is arranged on the wiring substrate 10. Also, the glass epoxy resin layer 40 is adhered onto the wiring substrate 10 with the adhesive layer 42 by curing the adhesive layer 42 by means of the heat treatment.

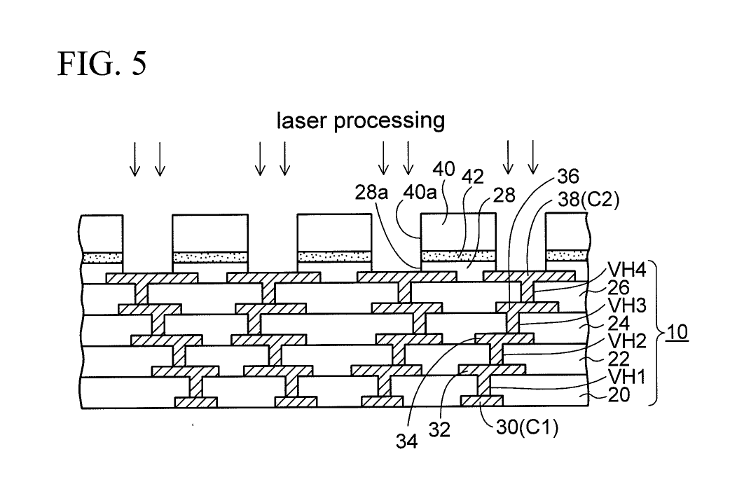

Then, as shown in FIG. 5, the glass epoxy resin layer 40 and the adhesive layer 42 are processed by the laser, and thus opening portions 40a are formed to expose the connection terminal pads C2. The opening portions 40a in the glass epoxy resin layer 40 and the adhesive layer 42 are formed in the same regions as the opening portions 28a in the solder resist 28. The opening portions 40a may be formed by the sandblasting process or the milling process, instead of the laser processing.

With the above, the glass epoxy resin layer 40 in which the opening portions 40a are provided in portions corresponding to the connection terminal pads C2 respectively is formed on the wiring substrate 10, and constitutes the supporting plate. Accordingly, even though the wiring substrate 10 made thin whose rigidity is low is employed, the wiring substrate 10 is supported and reinforced by the glass epoxy resin layer 40 (supporting plate). As a result, such a situation can be prevented that, even when the external stress is applied, the wiring substrate 10 is bent and deformed.

(Second Forming Method of Supporting Plate)

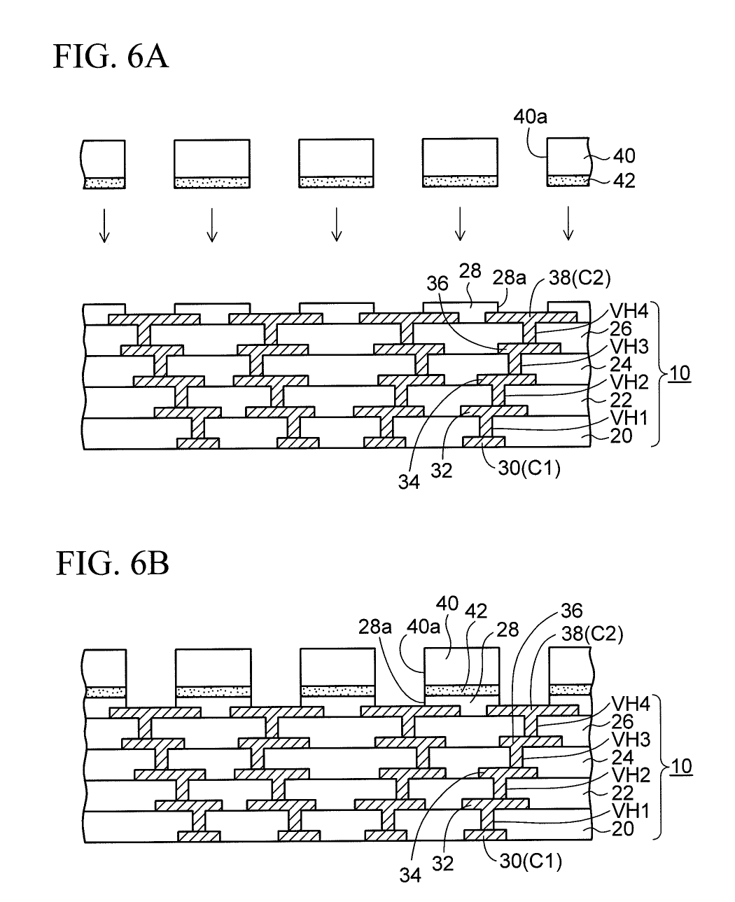

As shown in FIG. 6A, the glass epoxy resin layer 40 on the lower surface side of which the adhesive layer 42 is provided may be provided, and then the opening portions 40a may be formed previously by punching out by means of the stamping process. The opening portions 40a are formed to correspond to the connection terminal pads C2 of the wiring substrate 10. Then, as shown in FIG. 6B, the glass epoxy resin layer 40 and the adhesive layer 42 in which the opening portions 40a are formed are arranged on the wiring substrate 10, and the adhesive layer 42 is cured by means of the heat treatment. Accordingly, as shown in FIG. 6B, the same structure as that in FIG. 5 can be obtained.

(Third Forming Method of Supporting Plate)

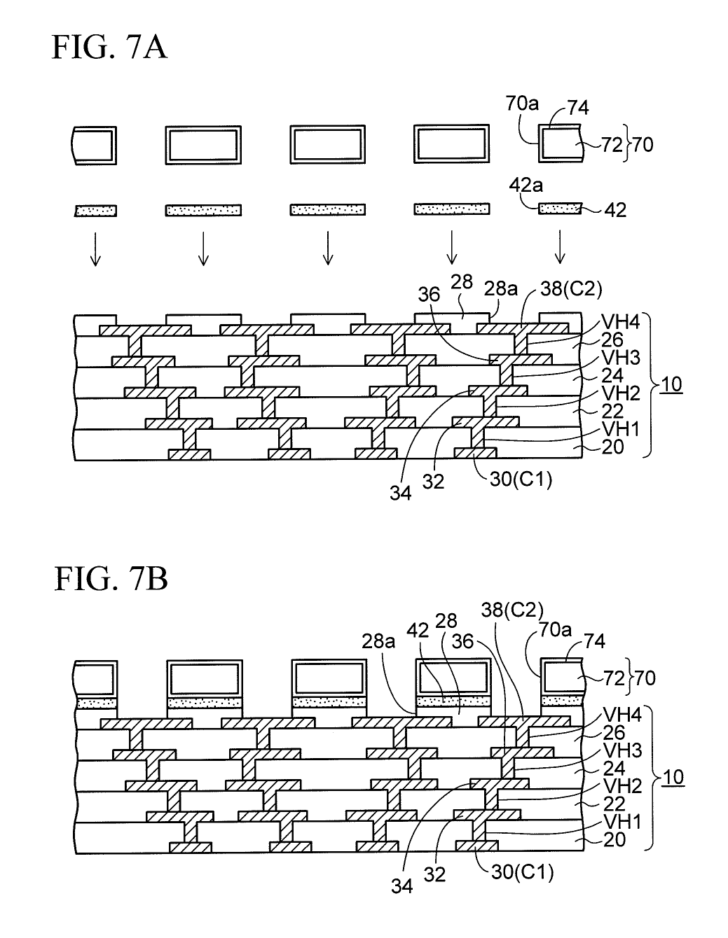

In a third forming method, the insulating metal plate is employed as the supporting plate. As shown in FIG. 7A, opening portions 70a are formed by punching out a metal plate 72 by means of the stamping process. A metal oxide layer is formed on the whole surfaces containing inner walls of the opening portions 70a in the metal plate 72. Thus, an outer surface of the metal plate 72 is covered with an insulating layer 74. Accordingly, an insulating metal plate 70 in which the opening portions 70a are provided and to the outer surface of which the insulating process is applied is obtained. The opening portions 70a in the insulating metal plate 70 are formed to correspond to the connection terminal pads C2 of the wiring substrate 10.

As the metal plate 72, an aluminum plate, a copper plate, or the like is employed. When the aluminum plate is employed, the insulating layer 74 is formed by applying the alumite process to the whole surface. Also, when the copper plate is employed, a copper oxide layer is formed on the whole surface by the blackening process, and thus the insulating layer 74 is formed.

Alternatively, the insulating layer 74 may be formed by coating the outer surface of the metal plate 72 with a resin. The resin is cured by the heat treatment after the resin is formed on the outer surface of the metal plate 72. The resin may be formed by dipping the metal plate 72 in a resin liquid, or the resin may be coated on the outer surface of the metal plate 72 by the spray. Otherwise, the resin may be formed on the outer surface of the metal plate 72 by the electrodeposition.

Then, the foregoing sheet-like adhesive layer 42 is prepared, and then punched out by the stamping process. Thus, opening portions 42a corresponding to the opening portions 70a in the insulating metal plate 70 are formed in the adhesive layer 42.

Then, as shown in FIG. 7B, the insulating metal plate 70 is arranged on the wiring substrate 10 via the adhesive layer 42, and is heat-treated. Thus, the insulating metal plate 70 is adhered onto the wiring substrate 10 by the adhesive layer 42.

Accordingly, the insulating metal plate 70 in which the opening portions 70a are provided on the connection terminal pads C2 of the wiring substrate 10 is formed, and constitutes the supporting plate.

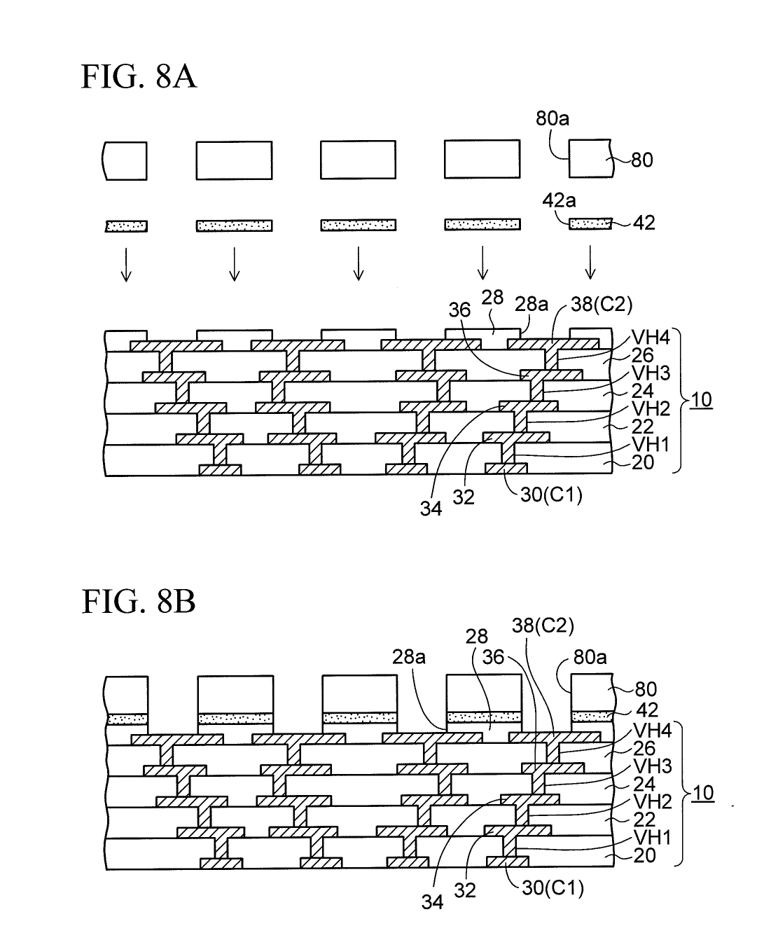

Alternatively, as shown in FIG. 8A, a ceramic plate 80 such as alumina, or the like may be employed instead of the insulating metal plate 70. In this case, first, opening portions 80a are formed in the ceramic plate 80 by the drilling or the like. Then, the opening portions 42a corresponding to the opening portions 80a in the ceramic plate 80 are formed in the sheet-like adhesive layer 42. Then, as shown in FIG. 8B, the ceramic plate 80 is adhered onto the wiring substrate 10 by the adhesive layer 42, and constitutes the supporting plate.

(Fourth Forming Method of Supporting Plate)

In a fourth forming method, the resin layer in the B stage (semi-cured state) is employed with a single layer as the supporting plate. As the resin layer in the B-stage, the same resin (prepreg, epoxy resin, acrylic resin, or the like) as the adhesive layer 42 explained in the first forming method is employed.

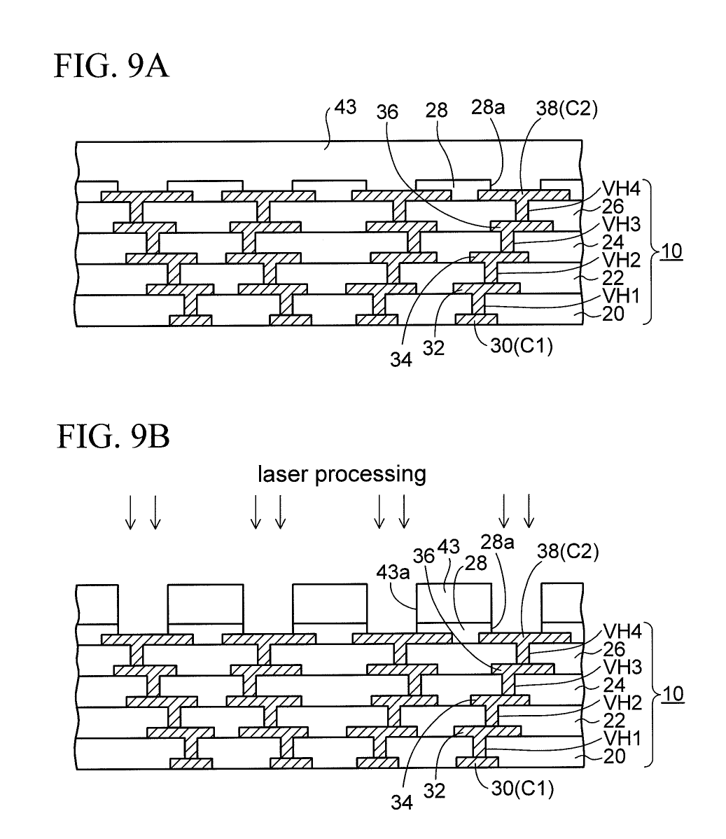

As shown in FIG. 9A, a sheet-like resin layer 43 in the B stage (semi-cured state) is arranged on the wiring substrate 10. Then, the resin layer 43 is cured by the heat treatment and is adhered onto the wiring substrate 10. Since the resin layer 43 in the B stage itself has an adhering function, such resin layer when cured is adhered onto the wiring substrate 10.

Then, as shown in FIG. 9B, opening portions 43a are formed in the resin layer 43 by the laser processing to expose the connection terminal pads C2. Accordingly, the resin layer 43 in which the opening portions 43a corresponding to the connection terminal pads C2 are provided is formed on the wiring substrate 10, and constitutes the supporting plate.

In this case, the opening portions 43a may be formed previously in the resin layer 43 by the stamping process, and then the resin layer 43 may be adhered onto the wiring substrate 10.

As described above, as the supporting plate for reinforcing the wiring substrate 10 made thin, preferably the resin layer containing fiber reinforcing material (the glass epoxy resin layer), the insulating body such as the ceramic plate 80, the thermosetting resin layer 43, or the like, the insulating metal plate 70 to the outer surface of which the insulating process is applied, or the like should be employed.

In the first to fourth forming methods of the supporting plate, the supporting plate can be formed collectively on a large number of wiring substrate portions B in the state of the large-size substrate 5 for the multi production in FIG. 3B. Therefore, the semiconductor package having the supporting plate can be manufactured effectively by the existing manufacturing line.

Next, a method of fitting the lead pins to the wiring substrate 10 on which the supporting plate is formed will be explained hereunder. In the first embodiment, the wiring substrate 10 on which the glass epoxy resin 40 is formed as the supporting plate is enumerated as an example, and a method of fitting the lead pins to the wiring substrate will be explained herein.

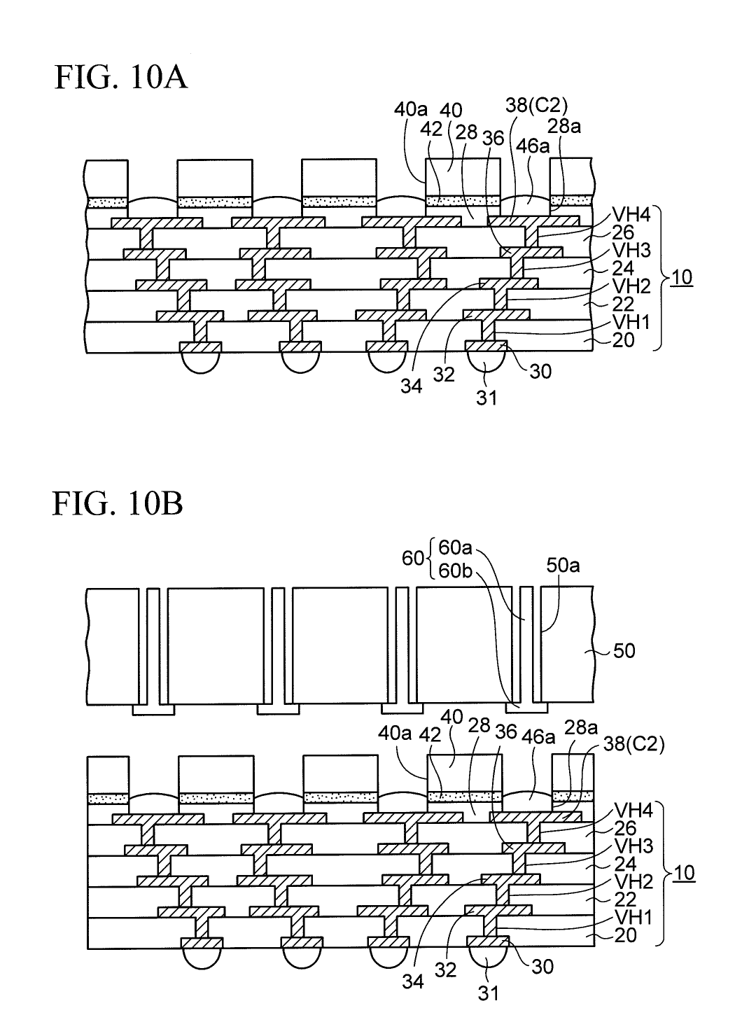

As shown in FIG. 10A, a solder material 46a is formed on the connection terminal pads C2 of the wiring substrate 10 by the printing, or the like respectively. Also, a solder bump 31 is formed on (in FIG. 10A, under) the chip connection pads C1 of the wiring substrate 10 respectively.

Here, before the lead pins are fitted to the wiring substrate 10, the large-size substrate 5 is cut off to get respective wiring substrate portions B of the above large-size substrate 5 in FIG. 3B described above. Accordingly, individual wiring substrates 10 shown in FIG. 10B can be obtained.

Then, as also shown in FIG. 10B, a pin mounting jig 50 for fitting the lead pins is prepared. A plurality of insertion holes 50a are provided in the pin mounting jig 50, and the insertion holes 50a correspond to the connection terminal pads C2 of the wiring substrate 10.

Then, a lead pin 60 is inserted into the insertion holes 50a of the pin mounting jig 50 respectively. The lead pin 60 is constructed by a pin portion 60a, and a head portion 60b provided to one end side of the lead pin 60 as a large diameter portion. Also, the lead pin 60 is constructed by coating nickel layer/gold layer sequentially from the bottom on a surface of the pin main body which is formed of copper or copper alloy, for example.

The pin portion 60a of the lead pin 60 is inserted into the insertion holes 50a of the pin mounting jig 50 respectively, and the head portions 60b are held on the surface of the pin mounting jig 50. Actually, the head portions 60b of the lead pins 60 are held on the upper surface of the pin mounting jig 50 in a state that top and bottom reverse in FIG. 10B.

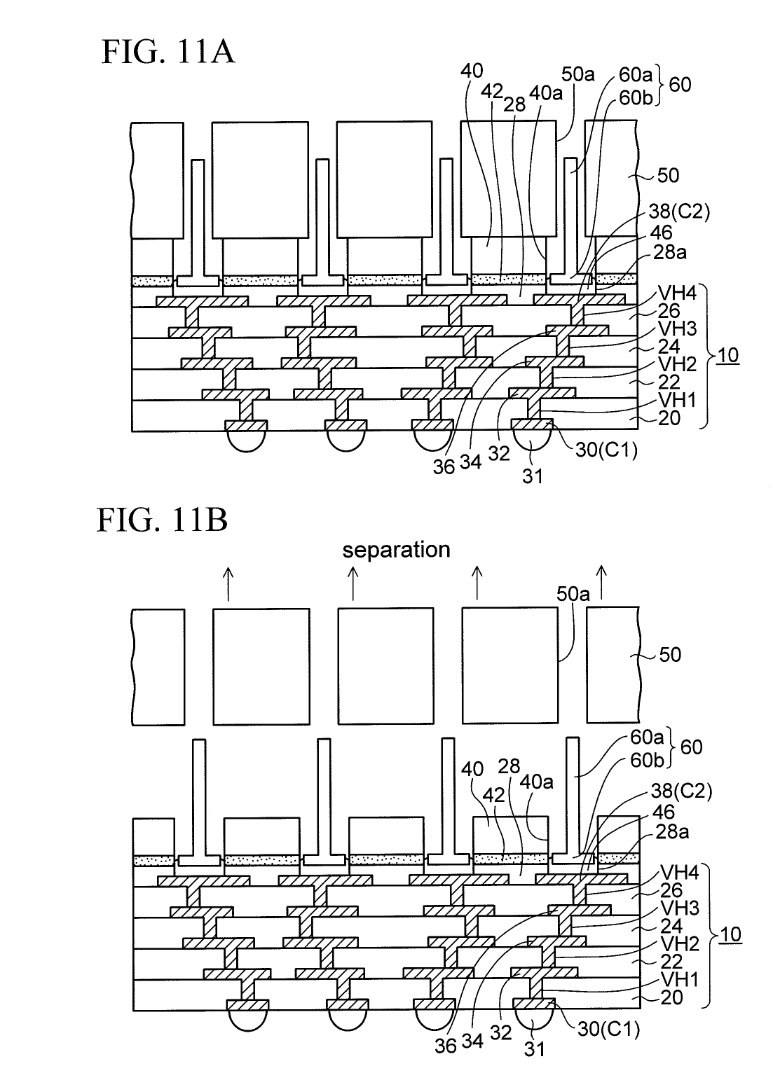

Then, as shown in FIG. 11A, while the pin mounting jig 50 on which a plurality of lead pins 60 are aligned is opposed to the connection terminal pads C2 of the wiring substrate 10, the head portions 60b of the lead pins 60 are pushed onto the solder materials 46a provided on the connection terminal pads C2 of the wiring substrate 10. Then, the solder materials 46a are reflow-heated. Accordingly, the lead pins 60 are fixed to the connection terminal pads C2 of the wiring substrate 10 by a solder layer 46.

Then, as shown in FIG. 11B, the pin mounting jig 50 is separated from the wiring substrate 10. At this time, the glass epoxy resin layer 40 (supporting plate) is provided on the surface of the wiring substrate 10 made thin onto which the lead pins 60 are fitted.

Consequently, even though the inclined lead pins 60 in the above related art contact the pin mounting jig 50 and act as the resistance, the wiring substrate 10 is neither bent nor deformed, and therefore the pin mounting jig 50 can be separated stably from the wiring substrate 10.

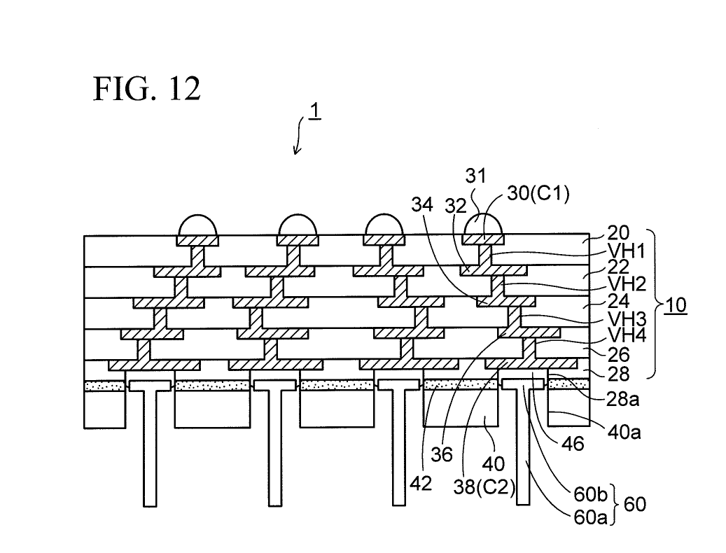

With the above, as shown in FIG. 12, a semiconductor package 1 of the first embodiment can be obtained. In FIG. 12, the wiring substrate 10 to which the lead pins 60 in FIG. 11B are fitted is drawn in a state that top and bottom reverse.

As shown in FIG. 12, in the wiring substrate 10 of the semiconductor package 1 of the first embodiment, the wiring substrate 10 explained in FIG. 3A is arranged in a state that top and bottom reverse. That is, the back surfaces of the first wiring layers 30 formed firstly when forming the build-up wiring layer serve as the chip connection pads C1 for mounting the semiconductor chip, while the top surfaces of the fifth wiring layers 38 formed lastly serve as the connection terminal pads C2 for connecting the lead pins 60.

The uppermost first wiring layers 30 are embedded in the upper portion of the first interlayer insulating layer 20, and the upper surfaces of the first wiring layers 30 and the upper surface of the first interlayer insulating layer 20 constitute the identical surface. The solder bump 31 for mounting the semiconductor chip is formed on the chip connection pads C1 respectively.

The second to fifth wiring layers 32, 34, 36, 38 are formed to be stacked sequentially under the first wiring layers 30 via the first to fourth interlayer insulating layers 20, 22, 24, 26. The first to fifth wiring layers 30, 32, 34, 36, 38 are connected mutually via the via holes VH1 to VH4 (via conductors) provided in the interlayer insulating layers 20, 22, 24, 26 between them.

The solder resist 28 in which the opening portions 28a are provided on (in FIG. 12, under) the connection terminal pads C2 is formed on the lower surface side of the wiring substrate 10. The glass epoxy resin layer 40 (supporting plate) is adhered under the solder resist 28 by the adhesive layer 42. The opening portions 40a corresponding to the connection terminal pads C2 are provided in the glass epoxy resin layer 40 and the adhesive layer 42. The opening portion 40a in the glass epoxy resin layer 40 and the adhesive layer 42 is formed every connection terminal pad C2.

Then, the lead pin 60 is fixed onto the connection terminal pads C2 of the wiring substrate 10 by the solder layer 46 respectively.

In the semiconductor package 1 of the first embodiment, the supporting plate such as the glass epoxy resin layer 40, or the like having a thickness of 0.7 mm to 0.2 mm is provided to the surface to which the lead pins 60 are fitted. Therefore, the wiring substrate 10 has a sufficient rigidity even when such wiring substrate is made thin to 0.2 mm to 0.4 mm.

Therefore, particularly, when fitting the lead pins 60 by the pin mounting jig 50, no bend is caused in the wiring substrate 10 and the lead pins 60 can be fitted with good reliability. As a result, the equipment and the jig used in manufacturing the semiconductor package in the prior art can be employed without change, and therefore a necessity of introducing the new equipment is eliminated and a development cost can be suppressed.

When a thickness of the supporting plate is set to 25 to 100% of a thickness of the wiring substrate 10, a sufficient mechanical strength of the wiring substrate 10 and the semiconductor device described later can be obtained.

Also, in measuring a tensile strength of the lead pin 60, the wiring substrate 10 is neither bent nor deformed. Therefore, a precise tensile strength of the lead pin 60 can be measured.

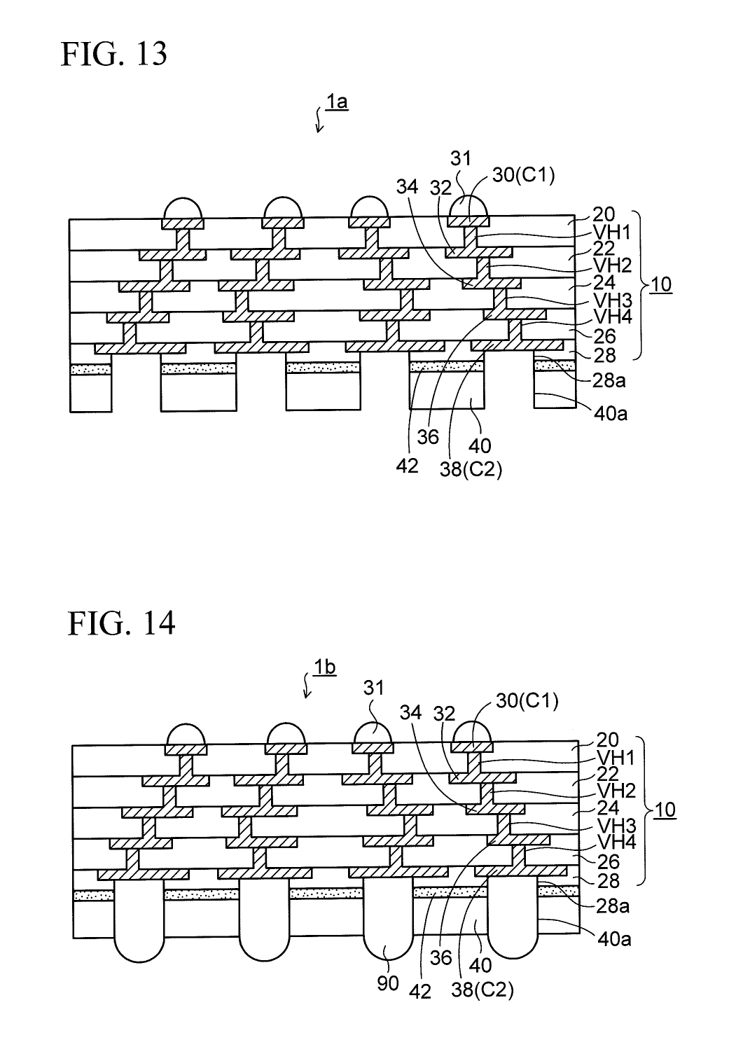

The semiconductor package 1 of the first embodiment possesses such an advantage that occurrence of the bend in fitting the lead pins 60 can be prevented. In this case, like a semiconductor package 1a shown in FIG. 13, the lead pins 60 are not provided to the connection terminal pads C2 of the wiring substrate 10, and the connection terminal pads C2 may be used as the lands. In the case of this mode, the semiconductor package 1a is of the LGA (Land Grid Array) type, and the bump electrodes are provided on the mounting substrate side. Upon mounting the semiconductor package 1a on which the semiconductor chip is mounted on the mounting substrate by using a mounter, the deformation caused due to the external stress can be prevented, and also the semiconductor package 1a can be connected with good reliability.

Alternatively, like a semiconductor package 1b shown in FIG. 14, solder bumps 90 protruded from the glass epoxy resin layer 40 (supporting plate) may be formed on the connection terminal pads C2 instead of the lead pins 60. Also, in addition to the solder bumps 90, various projection-like external connection terminals may be provided. In this case, similarly the deformation of the wiring substrate 10 caused in forming the solder bumps 90 can be prevented, and also the semiconductor package 1b on which the semiconductor chip is mounted can be connected to the mounting substrate with good reliability.

In this manner, in the semiconductor packages 1, 1a, 1b of the first embodiment, the projection-like external connection terminals (the lead pins 60, the solder bumps 90, or the like) protruded from the supporting plate may be provided on the connection terminal pads C2, or the connection terminal pads C2 may be employed as the lands.

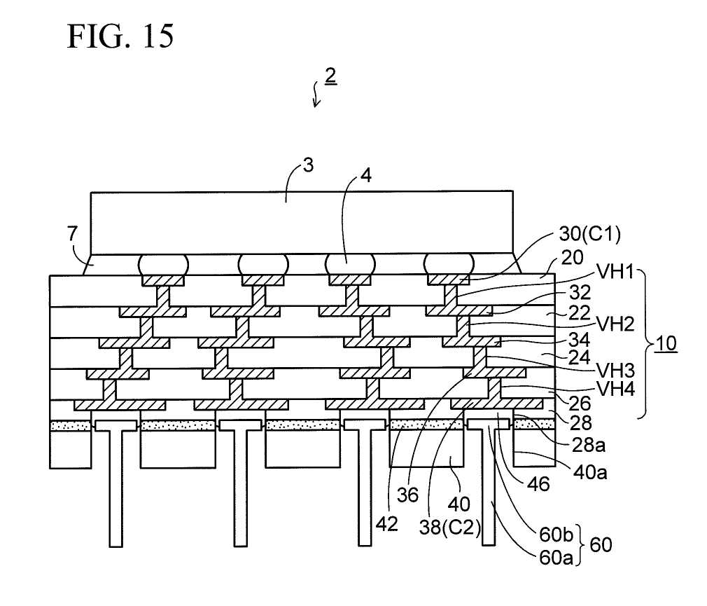

In FIG. 15, a semiconductor device 2 constructed by mounting the semiconductor chip on the semiconductor package 1 in FIG. 12 is shown. Connection electrodes (not shown) of a semiconductor chip 3 (LSI chip) are arranged on the solder bumps 31 on the chip connection pads C1 of the semiconductor package 1 in FIG. 12, and then the reflow heating is applied. Hence, as shown in FIG. 15, the semiconductor chip 3 is flip-chip connected to the chip connection pads C1 of the wiring substrate 10 by bump electrodes 4. Then, an underfill resin 7 is filled into a space under the semiconductor chip 3.

In this manner, the semiconductor chip 3 is flip-chip connected to the chip connection pads C1 of the semiconductor package 1 on the opposite side to the lead pins 60 side, and thus the semiconductor device 2 of the first embodiment can be obtained. As described above, since the wiring substrate 10 is reinforced by the supporting plate, such a situation is never caused that the wiring substrate 10 is bent and deformed, and the semiconductor chip 3 can be mounted with good reliability.

Also, the semiconductor device may be constructed by mounting the semiconductor chip 3 on the semiconductor package 1a, 1b in above FIG. 13 and FIG. 14.

In FIG. 15, the semiconductor chip 3 is mounted on the first wiring layers 30 (connection pads C1) formed firstly when forming the build-up wiring layer on the temporary substrate 11, while the lead pins 60 are fitted to the fifth wiring layers 38 (connection pads C2) formed lastly.

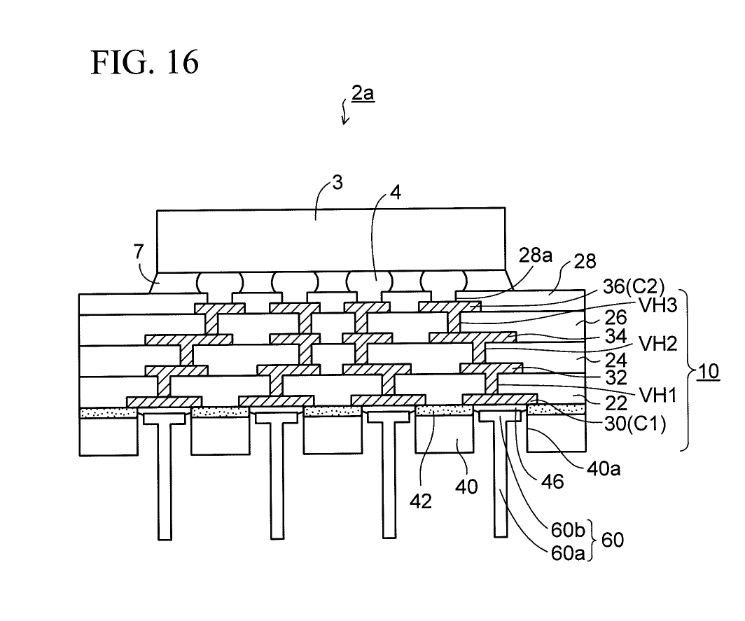

Conversely, like a semiconductor device 2a shown in FIG. 16, the lead pins 60 may be fitted to the first wiring layers 30 (connection pads C1) formed firstly when forming the build-up wiring layer on the temporary substrate 11, while the semiconductor chip 3 may be flip-chip connected to the fifth wiring layers 38 (connection pads C2) formed lastly.

That is, in the coreless type wiring substrate 10 having the connection pads on both sides, the semiconductor chip 3 can be mounted on any one connection pads and the lead pins 60 can be fitted to the other connection pads. Then, the supporting plate such as the glass epoxy resin layer 40, or the like is provided to the surface of the wiring substrate 10 onto which the lead pins 60 are fitted.

### Second Embodiment

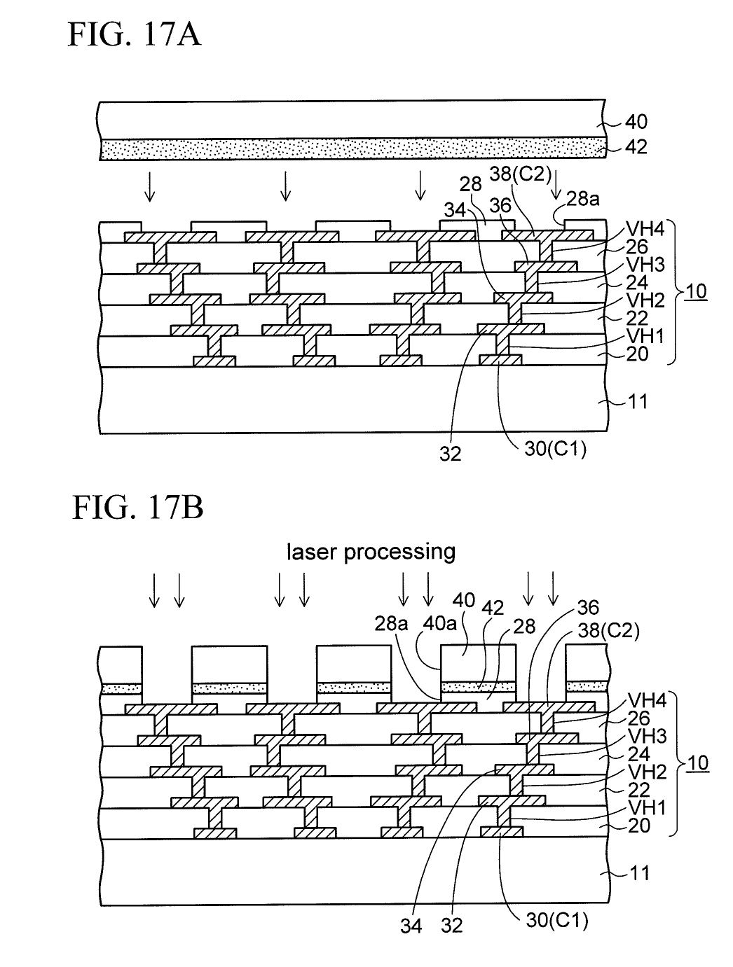

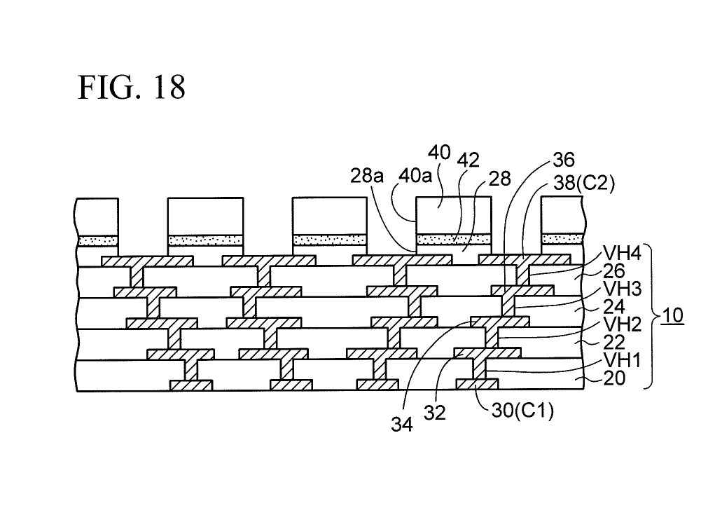

FIGS. 17A and 17B and FIG. 18 are sectional views showing a method of manufacturing a semiconductor package according to a second embodiment of the present invention. In the second embodiment, the same reference symbols are affixed to the same elements as those in the first embodiment, and their explanation will be omitted herein.

In the second embodiment, as shown in FIG. 17A, the glass epoxy resin layer 40 (supporting plate) is adhered onto the wiring substrate 10 by the adhesive layer 42 in a state that the wiring substrate 10 is formed on the temporary substrate 11.

Then, as shown in FIG. 17B, like the steps in FIG. 5 in the above first embodiment, the opening portions 40a are formed on the connection terminal pads C2 by applying the laser processing to the glass epoxy resin layer 40 and the adhesive layer 42.

Then, as shown in FIG. 18, the temporary substrate 11 is removed from the wiring substrate 10. Accordingly, the same structure as that shown in FIG. 5 of the first embodiment can be obtained.

Then, the semiconductor package 1 similar to that in the first embodiment can be obtained by carrying out the steps in FIG. 10A to FIG. 11B of the first embodiment.

In the second embodiment, the glass epoxy resin layer 40 (supporting plate) is adhered onto the wiring substrate 10 and then the opening portions 40a are formed on the connection terminal pads C2 by the laser processing in a state that the wiring substrate 10 made thin is reinforced by the temporary substrate 11. Therefore, the handling of the wiring substrate 10 made thin can be facilitated rather than the first embodiment, and the supporting plate can be formed with good reliability. This is similar also in the case where the second to fourth forming methods of the supporting plate explained in the first embodiment are employed.

What is claimed is:

1. A semiconductor package, comprising:
a wiring substrate having a connection pad on both surface sides respectively; and
a supporting plate provided on one surface side of the wiring substrate and formed of an insulator in which an opening portion is provided in a portion corresponding to the connection pad.

2. A semiconductor package according to claim 1, further comprising:
a lead pin fixed to the connection pad of a surface of the wiring substrate, on which the supporting plate is provided, by a solder layer.

3. A semiconductor package according to claim 1, wherein the supporting plate is formed of any one of a resin layer containing fiber reinforcing material, a ceramic plate, and a thermosetting resin layer.

4. A semiconductor device, comprising:
the semiconductor package set forth in any one of claims 1 to 3; and
a semiconductor chip mounted on the connection pad on an opposite side to a surface of the semiconductor package on which the supporting plate is provided.

5. A method of manufacturing a semiconductor package, comprising the steps of:
preparing a wiring substrate having a connection pad on both surface sides respectively; and
forming a supporting plate formed of an insulator in which an opening portion is provided in a portion corresponding to the connection pad, to one surface side of the wiring substrate.

6. A method of manufacturing a semiconductor package, according to claim 5, after the step of forming the supporting plate, further comprising the steps of:
forming a solder material on the connection pad on a surface side of the wiring substrate on which the supporting plate is formed; and
connecting electrically a lead pin to the connection pad by a solder layer by arranging the lead pin on the solder material and then reflow-heating the solder material.

7. A method of manufacturing a semiconductor package, according to claim 5, wherein the supporting plate is formed of a sheet-like resin layer, and
the step of forming the supporting plate includes the steps of:
adhering the resin layer to the wiring substrate by an adhesive layer, and
forming the opening portion by processing the resin layer and the adhesive layer.

8. A method of manufacturing a semiconductor package, according to claim 5, wherein the supporting plate is formed of a sheet-like resin layer or a ceramic plate, and
the step of forming the supporting plate includes the steps of:
preparing the resin layer or the ceramic plate in which the opening portion corresponding to the connection pad is provided, and a sheet-like adhesive layer in which an opening portion is provided, and
adhering the resin layer or the ceramic plate to the wiring substrate by the adhesive layer.

9. A method of manufacturing a semiconductor package, according to claim 7, wherein the resin layer is formed of a resin layer containing fiber reinforcing material or a thermosetting resin layer.

10. A method of manufacturing a semiconductor package, according to claim 7, wherein a resin in a semi-cured state is employed as the adhesive layer, and
the resin layer or the ceramic plate is adhered by curing the resin in the semi-cured state by a heat treatment.
